(19) United States
(12) Patent Application Publication
(10) Pub. No.: US 2009/0174581 A1
(43) Pub. Date: Jul. 9, 2009

(54) INPUTTING METHOD OF COMPUTER AND MOBILE TELEPHONE

(76) Inventor: Zhongwei Zang, Jiangsu (CN)

Correspondence Address: Workman Nydegger;1000 Eagle Gate Tower, 60 East South Temple, Salt Lake City, UT, 84111, US

(21) Appl. No.: 12/159,761

(22) PCT Filed: Dec. 27, 2006
(86) PCT No.: PCT/CN2006/003620

§ 371 Date: Oct. 16, 2008

(30) Foreign Application Priority Data
Dec. 28, 2005 (CN) 200510048327.7
Apr. 9, 2006 (CN) 200610074441.1
Jun. 29, 2006 (CN) 200610100437.8

(51) Int. Cl. H03M 11/00; G06F 17/20

(52) U.S. Cl. 341/23; 704/8

(57) ABSTRACT

An inputting method of computer and mobile telephone is disclosed. It is necessary for this method that there are 36 base codes and 5 single strokes. The base codes and the single strokes are configured on the 10 digits keys. It can input character without picking up it. The coding rule of all the words is same. It can directly input words with associative character for mobile telephone which has multiple selecting keys. The selecting keys are configured to multiple columns and multiple rows. When inputting English, it can input “space” automatically. For the high frequency word, it can display the word by only one key. That is to say a person can display text by pushing the selecting key only once. It can improve traditional inputting by associative character when a person uses computer.

### FIELD OF THE INVENTION

The present invention relates to an inputting method for computer, and mobile phone etc, in details, it is a digital coding based inputting method.

### BACKGROUND OF THE INVENTION

The present invention is designed based on the applicant's prior patent applications “Full-skip three-multiple input of Chinese character method” (2005100483277), “automatic space input method of English” (2006100744411) and “2D selection of Chinese input method” (2006101004378), and the present inputting method is the further improvement of all three input methods mentioned above.

### SUMMARY OF THE INVENTION

The present invention aims to provide an easy-to-use computer and mobile phone inputting method, this input method is simple, comprehensive, and suitable for the input of Chinese character, English, digit and symbol.

The technical solution for this present invention is as below:

10 digital keys or letter keys are selected on the keyboard for inputting the characters, after each one of Chinese character or letter input, multiple lines and multiple rows of associated Chinese character or English words can be displayed on the screen.

The Chinese characters are consisted of the elements and strokes. The digital key 1 is marked with the single stroke [symbol] and input elements [symbol] the digital key 2 is marked with input elements [symbol] and single strokes [symbol] the digital key 3 is marked with input elements [symbol] and single stroke [symbol] the digital key 4 is marked with input elements [symbol] and single stroke [symbol] the digital key 5 is marked with input elements [symbol] and single stroke [symbol] the digital key 6 is marked with input elements [symbol] the digital key 7 is marked with input elements [symbol] the digital key 8 is marked with input elements [symbol] [symbol] the digital key 9 is marked with input elements [symbol] [symbol] and the digital key 0 is marked with input elements [symbol] the input elements and single strokes on the digital keys can be interchanged or properly added/deleted. The coding rule for Chinese character is, firstly use the input element, fully skipped, take the 4^{th} element, or the 3^{rd} element and the 5^{th} element according to the writing sequence, after used and found the input element is inadequate, and no input element can be used, the single stroke can be taken, take the 1^{st}, 2^{nd}, 3^{rd} and final single stroke (behind the input element); if the input element is a part of final stroke, then it shall be the same as that of final stroke, can't be taken firstly; for the coding of punctuation symbols, 2 or 0 equals to 1-bit code, which can be displayed with only one key; the code fetching rule for all words, and phrases are just the same: for example, one word is ABC . . . N, the code fetching rule is A2 N3, that is: all words and phrases can take the first two codes of the first character and the first three codes of the final character, if inadequate for coding, added 0, or, added the final code; the code fetching rule is also as below: A1 N3, A1 N4, A1 N5, A2 N2, A2 N3, A2 N4, A3 N1, A3 N2, A3 N3, A4 N1, A4 N2, A5 N1 and A1 B2 N, A1 B3 N, A1 B4 N, A2 B1 N, A2 B2 N, A2 B3 N, A3 B1 N, A3 B2 N, A4 B1 N, A2 B2 N, take the first two bits of coding for the first and second characters and the final code of the final character, and it can also take the first two codes of the first character, the first code of the second character and the final code of the final character; take the first two codes of the first character and the first three codes of the second character; take the first two codes of the first character, the first three codes of the second character and the final code of the final character; take the first two bits of the first character, the first two bits of the final character and final code; without any change of the rule and input element (or properly interchanged, added/deleted the input elements), the traditional Chinese character can be input. The traditional Chinese character, simplified Chinese character belong to two different versions, or two different systems of same one version, if the system properly selected, the traditional Chinese character can be input, just like some network page “if want to display in Chinese, the English must be optional”, if you want to display the simplified Chinese character, the traditional Chinese character must be optional, or if you want to display the traditional Chinese character, the simplified Chinese character must be optional, certainly, both the simplified Chinese character, and traditional Chinese character can be also mixed together to display; the codes of back-up character is one or two bits more than that of a frequently-used character (with the equal bits or one more bits compared with words), and arranged behind the word; only the strokes continuously linked together can form the input element, if two input elements have the commonly-used part, gets that with much more strokes, if have the same number of strokes, the first one can be taken; in order to ensure the inputting of character, the variant of input element can be set without division in detail.

On the computer, the digital key can be used for selecting the character, and DOWN is used for inputting, (on the keyboard, the digital key can be only used for selecting the character, and the Q, W . . . P below the digital key can be used for inputting); or, input the character with the digital key and select with DOWN key, (on the keyboard, the Q, W . . . P below the digital key can be used for selecting the character, for 1 key, through the key below 1, for 2 key, through the key below 2 . . . very easy to study); certainly, the secondary keyboard can be also used for inputting the characters.

On the mobile phone, the multiple information display (displayed in multiple lines and multiple rows) can be applicable, it can directly input the words, and also associated the words; 2D optional (including the optional of multiple lines and multiple rows, and also optional of only single line or single row), the mobile phone has several option keys, left function key, on-hook key, * key, UP, MIDDLE and DOWN of option key, # key; the number of rows and lines can be added/deleted freely, if encountered a word with more than one characters, displayed in single row; the characters and the words can be displayed in mixed mode or separated mode according to the using frequency, and deleted the heading and categorization etc; the space between rows can be added a vertical line, certainly, it can be without of a line or spaced one character; the option key or other color, font or no marks etc. could be displayed with the optional reverse color; the option key can be marked at the left or right, up, down of character, and word, marked orderly or disorderly; the option key and character can be displayed simultaneously, or firstly display the character, after pressed OK, then display the option key; if the displayed number of characters, and words more than the option key, then enter the movable option after page up/down; the option key can be added/deleted, during selecting, all idle keys such as LEFT/RIGHT, laterally pressed key and digital key of option key can be used as the option key; the left row of option keys includes: LEFT, <, on-hook, * key, the right row includes: UP, MIDDLE, and DOWN of option key, # key; if the laterally-pressed key or other keys are used for page up/down, both <, and > can be used as the option key; when input through PINYIN, 0 and 1 without letters can be used as the option key; after pressed 5, the idle 5, 7, and 9 can be used as the option key etc; the option key may be fixed and frequently used, and also not fixed and selected freely, or partially fixed; the place of option key on the screen can be fixed, and also changed freely or partially changed; it can also: only one row is removable option; the movable row may be left, right and middle, one side is the character, the other side is the word or both the character, and word mixed together; if displayed in two rows, one side is the character and the other side is the work simultaneously, the initial left row is the character, the right row is the word, press < to enter the character (both rows display the character or the right row is still the word), press > to enter the word (both rows are words or the left row is the character), the single row or multiple rows are optional; certainly, it can also firstly display the character, then display the word after the characters browsed, or firstly display the word, then display the character, and left word and right character etc; the upper part of screen is the text area, the lower part is the option area, and separated with the horizontal line (or free of line); moreover, the text area and selection area can be displayed in different screen, that is, the whole screen is the selection area, after pressed OK, the text area can be displayed; after returned to the edited text and no content in the selection area (or displayed as required), the [symbol] keys can be used for moving the cursor left and right, and UP, DOWN for moving the cursor upward and downward (or the cursor not moved, the text moves upward and downward to view the big text), the mobile phone is arranged with the line feed key, the first line should be automatically indented, if forbid to indent, it can be deleted; behind each letter, and each alphabet, the character, and word can be displayed, the character with the same letter and same syllable can be displayed on the same one line or row, moreover, it can also display the letter, alphabet and character, word in multiple lines and rows, or, no character, and word displayed, only the alphabet displayed.

For the input of English, the formed word is ahead non-formed word, or the non-formed word not displayed, if encountered a word with several letters, displayed in single row; the naturally formed word is ahead that of associated word, or the associated word is ahead the naturally formed word; different parts can be separated with horizontal line (or free of lines), it can be also arranged the different components (or not separated) according to the number of letters for a word in the order from less to more or from more to less, or arranged in the letter sequence, or the using frequency, or frequently-used word arranged in using frequency, or in letter sequence, or the number of letters, or different arrangement modes; only the formed word +1 can enter a text; shape association, associate the whole word according to the letter, sense association, associate the words and word group, and phrase etc according to one or more words in the above text, and continuously associate, combine the shape association with the sense association to enlarge the range of selection, reduce the unused words, when there is only one word for selecting, this word can be automatically displayed on the screen without inputting all letters, or not automatically displayed on the screen; if the word with the space to enter a text, the space may be not pressed, if continuously press the space, invalid once or still valid, the punctuation is placed in the space; then the English input method can input the letter, just +1 can finish the input, the letters without or with spaces to enter a text, if a is unable to determine whether the word or letter with or without space to enter a text, deleted if the space is unnecessary; or displayed the word with only one key, or displayed the words, digit and letter etc with just only one key; on a mobile phone, the arrangement of letters can be reset, ab is arranged on 1 key, c is arranged on 2 key, . . . xyz is arranged on 0 key, the punctuation can be separated from special symbols or mixed together, and arranged on 2 or other keys, and all digits, and letters etc can be displayed by only pressed once; it may be also not arranged with “letter input method”, and “digit input method”; and the letters can be also only arranged on 9 digit keys;

On a computer, the input of English may be also realized through entering a text, the first line of selection area is the letters to be actually input, press the space to enter into a text, or the actually input is directly entered into the text, after pressed the space, then the punctuation, the symbols such as punctuation etc can be directly entered into the text; directly press the Enter key, and punctuation key etc, to select the words and letter etc to be entered in the space line of selection area into the text; the next is the associated words, it is unnecessary to associate all words, it may only associate only a part of all words, and divided into several groups with horizontal line or not divided, and set up several option keys as required; or the symbols such as punctuation etc on computer can be set on one key, and entered into text by selecting.

On the mobile phone, * can input the special symbols, simultaneously used as the universal key, switching the capital and small symbols, # can input the space or no space key set, and interchanged, * may also input the space, and simultaneously used for switching the capital and small symbols etc; the space, and characters can be valid as necessary, input also without returning into the text edition, if used as option key, then the input space and symbols etc are invalid during making the selection; the computer keypad can input, the /, *, -, ENTER etc can be used as the option key, or the digital keys used as the option key, and also not used; the selection of input mode can be carried out through a menu mode; when input the website etc, only just press the option key, certainly it shall be still entered through clicking the mouse.

The present invention can be widely used for various modes such as words, alphabet etc and various cases such as menu selection etc and their variations, and all aspects such as inputting the characters on computer, inputting the characters on mobile phone, character searching on a dictionary, electronic notebook, inputting of traditional Chinese characters etc.

The present invention has the following advantages:

With high input speed, the input method is easy to study, effectively improves the input efficiency and effect, and very suitable for word processing on the computer, and mobile phone.

For this input method, the Chinese character coding rule is simple, with less input elements, easy to study and use, most of stroke order, and stroke are unconcerned with the coding, only inputting the elements, with less same codes, no need to page up/down for 3,500 commonly used characters.

On the mobile phone, the multiple lines and multiple rows are optional, and certainly provided with the optimum effect; and the single row option is also OK. For example: left function key, UP, MIDDLE, DOWN, and on-hook key, all five in the same row corresponding to the activity row on the screen are used as the option key. All these can be studied easily, no any marks required. Moreover, there are 10 digital keys for inputting the characters, with less same codes, only just 5×10 frequently used characters 1+1 may meet with the requirements of this purpose. Moreover, high information volume for direct association and input of words, greatly reduce the key impacted frequency, not only ensure its high speed, save the time, but also provide a “comfortable” feel.

English can be automatically spaced, and utilize the association input, the frequently used words can be displayed through only press one key, greatly reduce the frequency of impacting keys.

### DETAILED DESCRIPTION OF THE EMBODIMENTS

The present invention will be further described by the combination of embodiments:

The rhetorical method of substitutive can be used for inputting the Chinese character, any one component of Chinese character can be substituted for representing this character. In order to unify and realize the uniqueness, the following stipulations must be obeyed:

I. 10 Digits Represent 36 Input Elements and 5 Single Strokes. (Interchanged or Appropriately Added or Deleted could be Made as Required)

| Combination and | | |
|---|---|---|
| configuration of input | | |
| element and single stroke | Reading method | Association memory |
| 1 -( [symbol] | - [symbol] | - [symbol] [symbol] |
| 2 ;\\| ( [symbol] )\ [symbol] | [symbol] [symbol] | [symbol] ? [symbol] |
| 3 [symbol] [symbol] | [symbol] [symbol] | [symbol] [symbol] |
| 4 `( )\‘’ [symbol] | [symbol] [symbol] | [symbol] [symbol] |
| 5 [symbol] [symbol] | [symbol] [symbol] | [symbol] [symbol] |
| 6 [symbol] | [symbol] [symbol] | [symbol] [symbol] |
| 7 [symbol] | 7 [symbol] | [symbol] |
| 8 [symbol] [symbol] | [symbol] | [symbol] [symbol] |
| 9 [symbol] [symbol] | [symbol] | [symbol] [symbol] |
| 0 [symbol] | 0 [symbol] | 0 [symbol] |

The input element (for example: [symbol] indicates (takes [symbol] as the representation) a type of components with the similar shape, and same name and quantity of strokes.

The variants in ( ) is provided for inputting the characters, unnecessary for dividing in details. For example: [symbol]
Note: 1. only those continuously written input elements are valid. For example: [symbol] only the [symbol] no [symbol]
2. When both input elements have the commonly used part, the element with more strokes can be taken, for elements with same number of strokes, the preceding one can be taken, for example: [symbol] with [symbol] without “ ”.
II. Coding rule:
1. The input element should be firstly used, take the fourth or the third, fifth elements according to the writing sequence. For example: [symbol] 9918 [symbol] 3088
2. Only after no input element can be used, the single stroke can be used, take (after the input element) the 1^{st}, 2^{nd}, 3^{rd} and final single strokes; if the input element is a part of the final element, then just the same as the final stroke, can't be taken firstly. For example: [symbol] 4354 (if no input element, the single stroke can be used) [symbol] 2864 [symbol] 4315 [symbol] 6430 [symbol] 3548 [symbol] 5128 [symbol] 941 [symbol] 0844 [symbol] 4658 [symbol] 57 [symbol] 4511 [symbol] 8152 [symbol] 1093 [symbol] 7128 [symbol] 250 [symbol] 6534 [symbol] 113 [symbol] 79 [symbol] 8

Configure the fault tolerant code and universal key, also not configured. The frequently-used character such as [symbol] etc can be displayed with only one key, just use the 1+1 to finish the input.

The code of punctuation symbol is one-bit code of 2 or 0 etc, and displayed with only one key.

All words have the same code fetching rule, which is characteristic of this method.

If one word is ABC . . . N, the code fetching rule is A2 N3, that is: all words, and phrases get the first two codes of the first character and the first three codes of the final character. For example:

[symbol] 10811 [symbol] 06100 (if the code is inadequate, add 0) or, [symbol] 88521 (if the code is inadequate, add the final bit of this character)

And also the code fetching rule as below: A1 N3, A1 N4, A1 N5, A2 N2, A2 N3, A2 N4, A3 N1, A3 N2, A3 N3, A4 N1, A4 N2, A5 N1 and A2 B2 N (the first two codes of the first and second characters and the final code of the final character), A1 B2 N, A1 B3 N, A1 B4N, A2 B1 N, A2 B2N, A2 B3N, A3 B1 N, A3 B2N, A4 B1 N Or: the first two codes of the first character, the first two codes of the final character and the final code.

Without the rule and input element changed (or properly interchanged, added/deleted the input elements), the traditional Chinese character can be input. The traditional Chinese character, simplified Chinese character belong to two different versions, or two different systems of same one version, if the system properly selected, the traditional Chinese character can be input, just like some network page “if want to display in Chinese, the English must be optional”, if you want to display the simplified Chinese character, the traditional Chinese character must be optional, or if you want to display the traditional Chinese character, the simplified Chinese character must be optional, certainly, both the simplified Chinese character, and traditional Chinese character can be also mixed together to display; the back-up character should be five bits or six bits, and seven bits (with the equal bits or one more bits compared with words), arranged behind the word, the coding rule can be made an analog from four bits.

Associated with not only the character, but also the words, and continuously make the association. For example: [symbol] associate the [symbol] (associated with the Chinese character) from [symbol] then associate [symbol] (associated with the word) from [symbol] two continuous associations are used.

### III. Inputting Mode of Characters

On computer: the digital key can be use for selecting, and the DOWN can be used for inputting. On the keyboard, the digital key can be only used for selecting, and the Q, W . . . P below digital key can be used for inputting, just like a person initially study the organ, write the 1, 2, and 3 on the relevant organ keys.

Or, inputting the character with digital keys, and DOWN for selecting purpose. On a keyboard, the Q, W . . . P keys below the digital key can be used for selecting the characters, for 1 key, through the key below 1, for 2 key, through the key below 2 . . . very easy to study. Moreover, the Chinese characters can be also input with the digits on the keypad through a single hand.

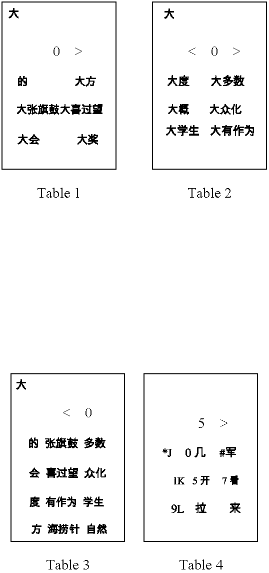

On a mobile phone, the multiple information can be displayed (displayed in multiple lines and rows), the words can be directly input, and also associated. For example: after input [symbol] the associated character, and words can be displayed. (Table 1)

2D selection (movable option of multiple lines and rows, and also movable option for only single line or row), on a mobile phone, there are several option keys: left function key, on-hook key, * key, and UP, MIDDLE and DOWN of option key, # key. If want to input [symbol] press the left function key, if want to input [symbol] press the on-hook key, if want to input [symbol] press the * key, if want to input [symbol] press the option key UP, if want to input [symbol] press the selection key DOWN, if want to input [symbol] [symbol] press the > to page up and display Table 2, then press the selection key MIDDLE. The number of lines and rows can be added and reduced as required, if encountered a word with many characters, displayed in single row. Both the character, and word can be displayed in mixing or separation mode according to the using frequency, just as Table 3: deleted the heading and categorization etc; the space between rows can be added a vertical line, certainly, it can be without of a line (Table 2) or spaced one character (Table 3);

The option key, other color, font or no mark etc. could be displayed or marked by the optional reverse color; the option key can be marked at the left or right, up, down of character, and word, marked orderly or disorderly; the option key and Chinese character can be displayed simultaneously, or firstly display the character, after pressed OK, then display the option key.

If the number of displayed characters and words are more than the option keys, then enter the movable option after page up/down; for example: if the left and middle row of Table 3 are optional, and the right row is not optional, if want to input the [symbol] press <, enter the left row to select; all the contents displayed in Table 6 are optional.

The option key can be added/deleted, during selecting, all idle keys such as LEFT/RIGHT, laterally pressed key and digital key of option key can be used as the option key; for example: if only the > used for page up/down, then the < is specified as the option key, thus Table 1 can be divided into 4 lines, the left row is the option keys: left key, <, on-hook key, * key, the right row is: UP, MIDDLE, and DOWN of option key, # key; if the laterally-pressed key or other keys are used for page up/down, both <, and > can be used as the option key; when input through PINYIN, 0 and 1 without letters can be used as the option key; after pressed 5, the idle 5, 7, and 9 can be used as the option key etc (Table 4); if want to input [symbol] just only press #. If want to input the [symbol] then press 3 to display Table 5 (just then the idle 2, 3, and 8 can be used for selecting), press 1 to display Table 6, just only press 5; certainly, when at Table 4, press 1, and then press other keys may also realize this purpose.

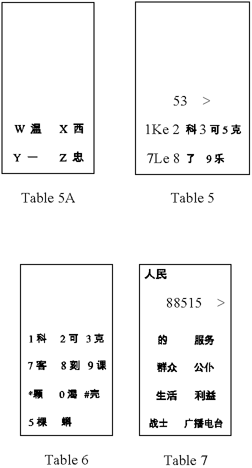

The option key may be fixed and frequently used, and also not fixed and selected freely, or partially fixed; for example: the left function key can be fixed as the option key, and also can't be used as the option key (just the same as Table 5), no # used in Table 5, and the # used in Table 6. The place of option key on the screen can be fixed, and also changed freely or partially changed; for example: the 5 is on the upper right of Table 5, and left down of Table 6.

It can also: only one row is removable option (Table 8), if want to input [symbol] press the left function key, if want to input the [symbol] press UP, if want to input [symbol] press DOWN, if want to input [symbol] press on-hook key, if want to input the [symbol] [symbol] press * key, if want to input the [symbol] press the # key, if want to input the “ [symbol] press the < (enter the movable left row) to display the Table 9, then press the MIDDLE key.

The movable row may be left, right and middle (Table 3), one side is the character, the other side is the word, or both the character and word mixed together; if displayed in two rows, one side is the character and the other side is the work simultaneously, the initial left row is the character, the right row is the word, press < to enter the character (both rows display the character or the right row is still the word), press > to enter the word (both rows are words or the left row is the character), the single row or multiple rows are optional; certainly, it can also firstly display the character, then display the word after the characters browsed; or firstly display the word, then display the character, or words are displayed on left and characters are displayed on right etc.

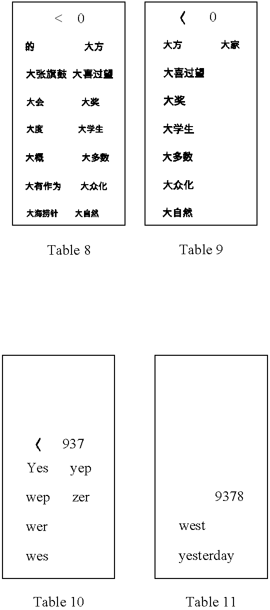

The upper part of screen is the text area, the lower part is the option area, and separated with the horizontal line (or without a line); moreover, the text area and selection area can be displayed in different screen, that is, the whole screen is the selection area, which can be displayed by pressing the input key, after pressed OK, the text area can be displayed; after returned to the edited text and no content in the selection area (or displayed as required), the [symbol] keys can be used for moving the cursor left and right, and UP, DOWN for moving the cursor upward and downward (or the cursor not moved, the text moves upward and downward to view the big text), the MIDDLE key is the line feed key, the first line should be automatically indented, if forbid to indent, it can be deleted;

It can be Seen from Table 4 and 5 that characters and words can be displayed behind each PINGYING and each alphabet, and the characters with the same letter and same syllable can be displayed on the same one line or row. Moreover, just as the same as Table 5A, it can also display the letter, alphabet and character, word in multiple lines and rows. Or only the letter and alphabet displayed without no character and word displayed, just as the same as the display of English in Table 10.

The Table 1 indicates the association from a character, but the word association is more practical. For example: [symbol] after selected the [symbol] the character association includes [symbol] etc, no [symbol] when associated in word [symbol] displayed Table 7, there is the [symbol] but no [symbol] etc. Associate according to one or more words in the above text, and continuously associate to realize the rapid and simple inputting. For example: [symbol] [symbol] the latter six characters can be input by pressing twice.

### IV For English, it May Also:

The formed word is ahead non-formed word, and the non-formed word is not displayed. For example: press 937 to display Table 10 (yes, or press 9 to display, or press 93 to display), if encountered a word with several letters, displayed in single row.

The naturally formed word is ahead that of associated word, or the associated word is ahead the naturally formed word; different parts can be separated with horizontal line (or without a line). It can be also arranged the different components (or not separated) according to the number of letters for a word in the order from less to more or from more to less, or arranged in the letter sequence, or the using frequency, or frequently-used word arranged in using frequency, or in letter sequence, or the number of letters, or also the different arrangement modes.

Only the formed word +1 can enter a text. For example: if wan to input yes (Table 10), press the left function key once to enter the text. If want to input yesterday, press 9378 to display Table 11 (or displayed with only one key). Hereby the “shape association” (associate the whole word according to the letter), and “sense association” (associate the words and word group, and phrase etc according to one or more words in the above text) are used, and continuously associate, for example: That is a book. Associate “is a” from “that”, then associate book (Table 12) from “is a”. When press b, the shape association can delete the desk etc, and replaced with a string of words with the heading of b, that is, combine the shape association with the sense association to enlarge the range of selection, reduce the unused words, when there is only one word for selecting, this word can be automatically displayed on the screen without inputting all letters, (if the word with the heading of b is only the book, then press b, the book can be entered) or not automatically displayed on the screen.

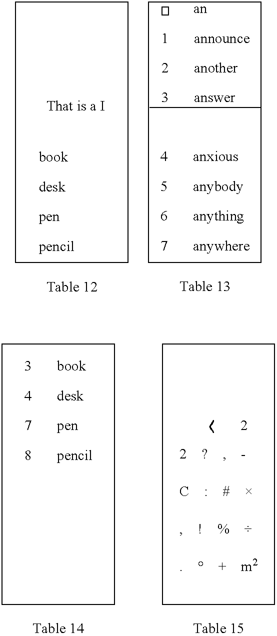

If a word be entered to a text with the space key, as Table 12, the space behind “a” can be entered only press the option key, the space may be not pressed, if continuously press the space. Invalid once (or still valid), the full stop behind the book can be placed in the space.

Then the English input method can input the letter, just use the +1, the letters without (or with) spaces can be entered to a text. When “a” is unable to determine whether it is the word or letter, enter with (or without) space to a text, deleted if the space is unnecessary. Or displayed the word with only one key, or displayed the words, digit and letter etc with just only one key; for example: press 9 to display yes.

On a mobile phone, the arrangement of letters can be reset, for example, ab is arranged on 1 key, c is arranged on 2 key . . . xyz is arranged on 0 key, the punctuation can be separated from special symbols (or mixed together), and arranged on 2 or other keys, and all digits, and letters etc can be displayed by only pressed once; it may be also not arranged with “letter input method”, and “digit input method”. The letters can be also only arranged on 9 digit keys, for example: 0 key has no letters, which is specially used for inputting punctuation, and switching the capital and small symbols etc.

On a computer, the input of English may be also realized through entering a text, for example: Table 13 is the selection area on the computer, the first line of selection area is the letters to be actually input, press the space to enter into a text, (or the actually input is directly entered into the text), after pressed the space, then the punctuation, (the symbols such as punctuation etc can be directly entered into the text); directly press the Enter key, and punctuation key etc, to select the words and letter etc to be entered in the space line of selection area into the text (if unusual practice, do it just as conventional mode); the next is the associated words, it is unnecessary to associate all words, it may only associate only a part of all words, such as commonly used words, and words of a special discipline . . . , and divided into several groups with horizontal line (or not divided), and set up several option keys as required; for example, Table 14 is the sense association, only “3, 4, 7, 8” can be used as the option key, or the symbols such as punctuation etc on computer can be set on one key, and entered into text by selecting.

### V. Others

On the mobile phone, * can input the special symbols, simultaneously used as the universal key, switching the capital and small symbols, # can input the space or no space key set, (interchanged, for example, * may also input the space, and simultaneously used for switching the capital and small symbols); The space, and characters can be valid as necessary, the input also can be finished without returning into the text edition, (if used as option key, then the input space and symbols etc are invalid during making the selection). In general, this solution must be used flexibly, change and select the relevant contents as necessary. The inputting mode on mobile phone can be used for computer, and vice versa.

The firstly display of frequently used words and association input etc mentioned above can be widely used for various modes such as words, pingying etc and various cases such as menu selection etc and their variations, for example: a. computer keypad is used for inputting, the /, *, -, ENTER etc can be used as the option key, or the digital keys used as the option key (and also not used); b, the selection of input mode can be carried out through a menu mode; c, when input the website etc, just as Table 13, only just press the option key, certainly it also can be still entered through clicking the mouse.

1. An inputting method of computer, and mobile phone, wherein, select 10 digital keys or letter keys on the keyboard for inputting the characters, after inputting one Chinese character or letter, the associated Chinese characters or English words can be displayed on the screen in multiple lines and multiple rows; the Chinese character is divided into the input elements and strokes, the 10 digits of “1, 2, 3 . . . 9, 0” can represent 36 input elements and 5 single strokes:
The digital key 1 is marked with single stroke [symbol] and input elements [symbol]
The digital key 2 is marked with input elements [symbol] and single strokes “ [symbol]
The digital key 3 is marked with input elements [symbol] and single stroke “ [symbol]
The digital key 4 is marked with input elements [symbol] and single stroke [symbol]
The digital key 5 is marked with input elements [symbol] and single stroke [symbol]
The digital key 6 is marked with input elements [symbol]
The digital key 7 is marked with input elements [symbol]
The digital key 8 is marked with input elements [symbol]
The digital key 9 is marked with input elements [symbol]
The digital key 0 is marked with input elements [symbol]
The input elements and single strokes on the digital keys can be interchanged or properly added/deleted;
the coding rule for Chinese character is: firstly use the input element, fully skipped, take the fourth element, or third element and fifth element according to the writing sequence, after used and found the input element is inadequate, and no input element can be used, the single stroke can be taken, take the 1^{st}, 2^{nd}, 3^{rd} and final single stroke (behind the input element); if the input element is a part of final stroke, then it shall be as the same as that of final stroke which can't be taken firstly; the coding of punctuation symbols are 2 or 0 etc. 1-bit code which can be displayed with only one key; the code fetching rule for all words, and phrases are just the same: for example, one word is ABC . . . N, the code fetching rule is A2 N3, that is: all words and phrases can take the first two codes of the first Chinese character and the first three codes of the final Chinese character, if inadequate for coding, added 0, or, added the final code; the code fetching rule is also as below: A1 N3, A1 N4, A1 N5, A2 N2, A2 N3, A2 N4, A3 N1, A3 N2, A3 N3, A4 N1, A4 N2, A5 N1 and A1 B2N, A1 B3N, A1 B4N, A2 B1 N, A2 B2N, A2 B3N, A3 B1 N, A3 B2N, A4 B1 N, A2 B2 N, take the first two bits of coding for the first and second Chinese character and the final code of the final Chinese character, and it can also take the first two codes of the first Chinese character, the first code of the second Chinese character and the final code of the final Chinese character; take the first two codes of the first Chinese character and the first three codes of the second Chinese character; take the first two codes of the first Chinese character, the first three codes of the second Chinese character and the final code of the final Chinese character; take the first two bits of the first Chinese character, the first two bits of the final Chinese character and final code; the traditional Chinese character can be input without changing the rule and input element (or properly interchanged, added/deleted the input elements), the traditional Chinese character, simplified Chinese character belong to two different versions, or two different systems of same version, if the system properly selected, the traditional Chinese character can be input, just like some network page which “if want to display in Chinese, the English must be optional”, if you want to display the simplified Chinese character, the traditional Chinese character must be optional, or if you want to display the traditional Chinese character, the simplified Chinese character must be optional, certainly, both the simplified Chinese character, and traditional Chinese character can be also mixed together to display; the codes of back-up character is one or two bits more than that of a frequently-used character (with the equal bits or one more bit compare with the word), and arranged behind the word; only the strokes continuously linked together can form the input element, if two input elements have the commonly-used part, gets the one with much more strokes, if have the same number of strokes, the first one can be taken; in order to ensure the inputting of character, the variant of input element can be set without division in details.

2. The inputting method as describe in claim 1, wherein:
on the computer, the digital key can be used for selecting the Chinese character, and DOWN is used for inputting, (on the keyboard, the digital key can be only used for selecting the Chinese character, and the Q, W . . . P below the digital key can be used for inputting); or input the character with the digital key and select with DOWN key, (on the keyboard, the Q, W . . . P below the digital key can be used for selecting the character, for 1 key, through the key below 1, for 2 key, through the key below 2 . . . very easy to study); certainly, the secondary keyboard can be also used for inputting the characters;
on the mobile phone, the multiple information display (displayed in multiple lines and multiple rows) can be applicable, it can directly input the words, and also associated the words; 2D optional (including the optional of multiple lines and multiple rows, and also optional of only single line or single row), the mobile phone has several option keys, left function key, on-hook key, * key, UP, MIDDLE and DOWN of option key, # key; the number of rows and lines can be added/deleted freely, if encountered a word with more than one characters, displayed in single row; the character and word can be displayed in mixed mode or separated mode according to the using frequency, and deleted the heading and categorization etc; the space between rows can be added a vertical line, certainly, it can be without a line or spaced one character; The option key, other color, font or no mark etc. could be displayed or marked by the optional reverse color; the option key can be marked at the left or right, up, down of character, and word, marked orderly or disorderly; the option key and Chinese character can be displayed simultaneously, or firstly display the character, after pressed OK, then display the option key; if the number of displayed characters and words more than the option key, then enter the movable option after page up/down; the option key can be added/deleted, during selecting, all idle keys such as LEFT/RIGHT, laterally pressed key and digital key of option key can be used as the option key; the left row of option keys includes: LEFT, <, on-hook, * key, the right row includes: UP, MIDDLE, and DOWN of option key, # key; if the laterally-pressed key or other keys are used for page up/down, both <, and > can be used as the option key; when input through PINYIN, 0 and 1 without letters can be used as the option key; after pressed 5, the idle 5, 7, and 9 can be used as the option key etc; the option key may be fixed and frequently used, and also not fixed and selected freely, or partially fixed; the place of option key on the screen can be fixed, and also changed freely or partially changed; it can also: only one row is removable option; the movable row may be left, right and middle, one side is the character, the other side is the word or both the character and word mixed together; if displayed in two rows, one side is the character and the other side is the word simultaneously, the initial left row is the character, the right row is the word, press < to enter the character (both rows display the character or the right row is still the word), press > to enter the word (both rows are words or the left row is the character), the single row or multiple rows are optional; certainly, it can also firstly display the character, then display the word after the characters browsed, or firstly display the word, then display the character, and left word and right character etc; the upper part of screen is the text area, the lower part is the option area, and separated with the horizontal line (or without a line); moreover, the text area and selection area can be displayed in different screen, that is, the whole screen is the selection area, after pressed OK, the text area can be displayed; after returned to the edited text and no content in the selection area (or displayed as required), the [symbol] keys can be used for moving the cursor left and right, and UP, DOWN for moving the cursor upward and downward (or the cursor not moved, the text moves upward and downward to view the big text), the mobile phone is arranged with the line feed key, the first line should be automatically indented, if forbid to indent, it can be deleted; behind each alphabet, and each pingying, the character and word can be displayed, the character with the same letter and same syllable can be displayed on the same line or row, moreover, it can also display the alphabet, pingying character and word in multiple lines and rows, or, no character, and word displayed, only the letter and alphabet displayed.

3. The inputting method as described in claim 1, wherein, for the input of English, the formed word is ahead non-formed word, or the non-formed word not displayed, if encountered a word with several letters, displayed in single row; the naturally formed word is ahead that of associated word, or the associated word is ahead the naturally formed word; different parts can be separated with horizontal line (or free of lines), it can be also arranged the different components (or not separated) according to the number of letters for a word in the order from less to more or from more to less, or arranged in the letter sequence, or the using frequency, or frequently-used word arranged in using frequency, or in letter sequence, or the number of letters, or different arrangement modes; the formed word +1 can enter a text; shape association, associate the whole word according to the letter, sense association, associate the words and word group, and phrase etc according to one or more words in the above text, and continuously associate, combine the shape association with the sense association to enlarge the range of selection, reduce the unused words, when there is only one word for selecting, this word can be automatically displayed on the screen without inputting all letters, or not automatically displayed on the screen; if the word with the space to enter a text, the space may be not pressed, if continuously press the space, invalid once or still valid, the punctuation is placed in the space; then the English input method can input the letter, just +1 can finish the input, the letters without or with spaces to enter a text, if “a” is unable to determine whether the word or letter with or without space to enter a text, deleted if the space is unnecessary; or displayed the word with only one key, or displayed the words, digit and letter etc. with just only one key;
On a mobile phone, the arrangement of letters can be reset, ab is arranged on 1 key, c is arranged on 2 key . . . xyz is arranged on 0 key, the punctuation can be separated from special symbols or mixed together, and arranged on 2 or other keys, and displayed with all digits, and letters etc by only pressed once; it may be also not arranged with “letter input method”, and “digit input method”; and the letters can be also only arranged on 9 digit keys;
On a computer, the input of English may be also realized through entering a text, the first line of selection area is the letters to be actually input, press the space to enter into a text, or the actually input is directly entered into the text, after pressed the space, then the punctuation, the symbols such as punctuation etc can be directly entered into the text; the words and letter etc to be entered in the space line of selection area can be entered into the text by directly pressing the Enter key, and punctuation key etc; the next is the associated words, it is unnecessary to associate all words, it may only associate only a part of all words, and divided into several groups with horizontal line or not divided, and set up several option keys as required; or the symbols such as punctuation etc on computer can be set on one key, and entered into text by selecting.

4. The inputting method as described in claims 1, 2 or 3, wherein, on the mobile phone, * can input the special symbols and simultaneously used as the universal key to switch the capital and small symbols, # can input the space or no space key set and interchanged, * may also input the space and simultaneously used for switching the capital and small symbols etc; the space and characters can be valid as necessary, the input also can be finished without returning into the text edition, if used as option key, then the input space and symbols etc are invalid during making the selection; the computer keypad can also used to input, the /, *, -, ENTER etc can be used as the option key, or the digital keys used as the option key, and also not used; the selection of input mode can be carried out through a menu mode; when input the website etc, only just press the option key, certainly it shall be still entered through clicking the mouse.

5. The inputting method as described in claim 4, wherein, the present invention can be widely used for various modes such as characters, pinying etc and various cases such as menu selection etc and their variations, and all aspects such as inputting the characters on computer, inputting the characters on mobile phone, character searching on a dictionary, electronic notebook, inputting of traditional Chinese characters etc.
